(19) United States
(12) Patent Application Publication
(10) Pub. No.: US 2013/0094320 A1
(43) Pub. Date: Apr. 18, 2013

(54) ADDRESS TRANSFORMING CIRCUITS INCLUDING A RANDOM CODE GENERATOR, AND RELATED SEMICONDUCTOR MEMORY DEVICES AND METHODS

(71) Applicants: Jae-Ki YOO, Hwaseong-si (KR); Sang-Hyuk Kwon, Seoul (KR); Sang-Woong Shin, Seongnam-si (KR); In-Chul Jeong, Suwon-si (KR)

(72) Inventors: Jae-Ki YOO, Hwaseong-si (KR); Sang-Hyuk Kwon, Seoul (KR); Sang-Woong Shin, Seongnam-si (KR); In-Chul Jeong, Suwon-si (KR)

(73) Assignee: Samsung Electronics Co., Ltd.

(21) Appl. No.: 13/610,995

(22) Filed: Sep. 12, 2012

(30) Foreign Application Priority Data
Oct. 12, 2011 (KR) 10-2011-0104108

(51) Int. Cl. G11C 8/10; G11C 8/00

(52) U.S. Cl. 365/230.06; 365/230.01

(57) ABSTRACT

Address transforming methods are provided. The methods may include generating a power-up signal when a semiconductor memory device is powered-up. The methods may further include generating a randomized output signal in response to the power-up signal. The methods may additionally include transforming bits of a first address in response to the randomized output signal to generate a second address.

### CROSS-REFERENCE TO RELATED APPLICATION

This U.S. non-provisional application claims priority under 35 U.S.C. §119(a) to Korean Patent Application No. 10-2011-0104108, filed on Oct. 12, 2011, the disclosure of which is hereby incorporated by reference in its entirety.

### BACKGROUND

The present disclosure relates to address transforming circuits and address transforming methods.

In systems using a semiconductor memory device, a specific area of a memory cell array may be used more frequently than other areas of the memory cell array. Such frequent use of a specific area of the memory cell array may decrease the lifespan of the semiconductor memory device, and thus may reduce the reliability of the semiconductor memory device.

### SUMMARY

An address transforming circuit according to various embodiments may include a random code generator that is included in a semiconductor memory device and that is configured to generate a randomized output signal in response to a power-up signal generated when power supplied to the semiconductor memory device is turned on. The address transforming circuit may also include an address scrambler that is configured to transform bits of a first address in response to the randomized output signal to generate a second address.

In various embodiments, the circuit may further include a power-up signal generator configured to generate the power-up signal.

According to various embodiments, the circuit may further include further a ZQ code generator configured to generate a ZQ code based on an output impedance of the semiconductor memory device. Additionally, the circuit may further include a code control circuit configured to generate a random code based on the ZQ code and the randomized output signal of the random code generator.

In various embodiments, the code control circuit and/or the address scrambler may be configured to selectively reverse phases of bits of a memory bank enable signal of the semiconductor memory device in response to the randomized output signal of the random code generator,

According to various embodiments, the randomized output signal of the random code generator may include a first random code. Additionally, the random code may include a second random code that is generated based on the ZQ code and the first random code.

In various embodiments, the second random code may be generated based on a temperature of the semiconductor memory device and the ZQ code.

According to various embodiments, the circuit may include a lock code generator configured to generate a lock code based on a lock state of a clock signal. The circuit may additionally include a code control circuit that is configured to generate a random code based on the lock code and the randomized output signal of the random code generator.

In various embodiments, a lock operation of the clock signal may be performed by a delay locked loop circuit.

According to various embodiments, the random code may be generated based on the lock code and a temperature of the semiconductor memory device.

In various embodiments, the randomized output signal of the random code generator may be generated based on a temperature of the semiconductor memory device.

A semiconductor memory device according to various embodiments may include a memory cell array. The semiconductor memory device may also include an address transforming circuit that is configured to transform bits of a first address in response to a random code generated in the semiconductor memory device, and that is further configured to generate a transformed row address and a transformed column address. The semiconductor memory device may further include a row decoder that is configured to decode the transformed row address, and that is further configured to designate a specific row of the memory cell array based on the decoded row address. The semiconductor memory device may additionally include a column decoder that is configured to decode the transformed column address, and that is further configured to designate a specific column of the memory cell array based on the decoded column address. Additionally, the semiconductor memory device may be configured to generate a power-up signal when power supplied to the semiconductor memory device is turned on, and may be further configured to generate the random code in response to the power-up signal.

In various embodiments, the address transforming circuit may include a column address generating circuit that is configured to generate the transformed column address and a row address generating circuit that is configured to generate the transformed row address. Additionally, the column address generating circuit may be configured to generate individual bits of the transformed column address in response to respective individual bits of a column selection signal that corresponds to respective individual bits of the random code. Moreover, the row address generating circuit may be configured to generate individual bits of the transformed row address in response to respective individual bits of a row selection signal that corresponds to the respective individual bits of the random code.

According to various embodiments, the random code may be generated based on a temperature of the semiconductor memory device and a ZQ code generated based on an output impedance of the semiconductor memory device.

In various embodiments, the random code may be generated based on a temperature of the semiconductor memory device and a lock state of a clock signal.

An address transforming method according to various embodiments may include generating a power-up signal when a semiconductor memory device is powered-up. The method may also include generating a randomized output signal in response to the power-up signal. The method may additionally include transforming bits of a first address in response to the randomized output signal to generate a second address. The method may further include selecting a memory cell for data input or output using the second address.

In various embodiments, the randomized output signal may include a first random code. Additionally, the method may further include generating a ZQ code in response to an output impedance of the semiconductor memory device. Moreover, the method may also include generating a second random code based on the first random code and the ZQ code. Also, transforming the bits of the first address in response to the randomized output signal may include transforming the bits of the first address in response to the second random code.

According to various embodiments, the randomized output signal may include a first random code. Additionally, the method may further include generating a lock code in response to a lock state of a clock signal. Also, the method may additionally include generating a second random code based on the first random code and the lock code. Moreover, transforming the bits of the first address in response to the randomized output signal may include transforming the bits of the first address in response to the second random code.

In various embodiments, generating the randomized output signal may include generating the randomized output signal based on a temperature of the semiconductor memory device.

According to various embodiments, generating the randomized output signal may include changing values of the randomized output signal in response to a change in the temperature of the semiconductor memory device.

In various embodiments, transforming the bits of the first address in response to the randomized output signal may include transforming bits of a memory bank enable signal in response to the randomized output signal.

### BRIEF DESCRIPTION OF THE DRAWINGS

The above and other features and advantages of the disclosure will become more apparent in view of the attached drawings and accompanying detailed description.

FIG. 1 is a block diagram of an address transforming circuit in accordance with various embodiments of the inventive concept;

FIG. 2 is a block diagram of an address transforming circuit in accordance with various embodiments of the inventive concept;

FIGS. 3 and 4 are tables for explaining an address transforming method using random codes in the address transforming circuit shown in FIG. 2;

FIG. 5 is a view illustrating an example of a memory cell array designated through a bank address set by the address transforming method shown in FIGS. 3 and 4;

FIG. 6 is a table for explaining an address transforming method using random codes generated based on a temperature changes caused by a memory chip;

FIG. 7 is a block diagram of an address transforming circuit in accordance with various embodiments of the inventive concept;

FIG. 8 is a block diagram of an address transforming circuit in accordance with various embodiments of the inventive concept;

FIG. 9 is a circuit diagram illustrating an example of a column address generating circuit included in the address transforming circuit shown in FIG. 8;

FIG. 10 is a circuit diagram illustrating an example of a row address generating circuit included in the address transforming circuit shown in FIG. 8;

FIG. 11 is a block diagram illustrating an example of a semiconductor memory device including an address transforming circuit in accordance with various embodiments of the inventive concept;

FIG. 12 is a flowchart illustrating an address transforming method of a semiconductor memory device in accordance with various embodiments of the inventive concept;

FIG. 13 is a flowchart illustrating an address transforming method of a semiconductor memory device in accordance with various embodiments of the inventive concept;

FIG. 14 is a flowchart illustrating an address transforming method of a semiconductor memory device in accordance with various embodiments of the inventive concept;

FIG. 15 is a plan view illustrating a semiconductor module mounted with a semiconductor memory device including an address transforming circuit in accordance with various embodiments of the inventive concept;

FIG. 16 is a perspective view schematically illustrating a stacked semiconductor device including an address transforming circuit in accordance with various embodiments of the inventive concept; and

FIG. 17 is a block diagram illustrating an example of an electronic system in which a semiconductor memory device including an address transforming circuit is included in accordance with various embodiments of the inventive concept.

### DETAILED DESCRIPTION

Example embodiments are described below with reference to the accompanying drawings. Many different forms and embodiments are possible without deviating from the spirit and teachings of this disclosure and so the disclosure should not be construed as limited to the example embodiments set forth herein. Rather, these example embodiments are provided so that this disclosure will be thorough and complete, and will convey the scope of the disclosure to those skilled in the art. In the drawings, the sizes and relative sizes of layers and regions may be exaggerated for clarity. Like reference numbers refer to like elements throughout.

The terminology used herein is for the purpose of describing particular embodiments only and is not intended to be limiting of the embodiments. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of the stated features, integers, steps, operations, elements, and/or components, but do not preclude the presence or addition of one or more other features, integers, steps, operations, elements, components, and/or groups thereof.

It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. As used herein the term “and/or” includes any and all combinations of one or more of the associated listed items.

It will be understood that although the terms first, second, etc. may be used herein to describe various elements, these elements should not be limited by these terms. These terms are only used to distinguish one element from another. Thus, a first element could be termed a second element without departing from the teachings of the present embodiments.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein may be interpreted accordingly.

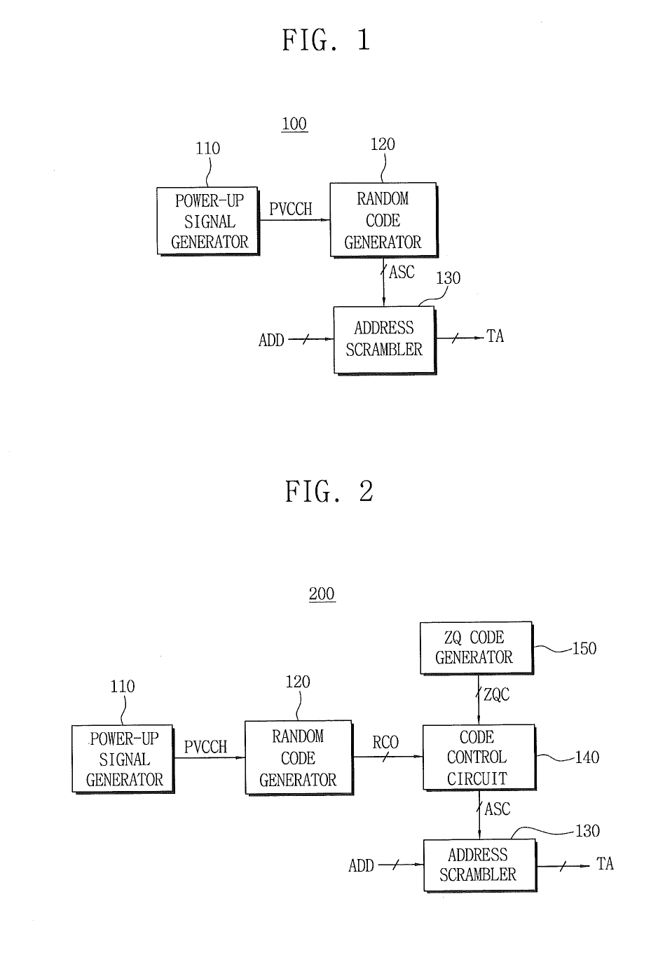

FIG. 1 is a block diagram of an address transforming circuit 100 in accordance with various embodiments of the inventive concept.

Referring to FIG. 1, the address transforming circuit 100 may include a power-up signal generator 110, a random code generator 120, and an address scrambler 130.

The power-up signal generator 110 generates a power-up signal PVCCH when power to be supplied to the semiconductor memory device (e.g., to a memory chip within the semiconductor memory device) is turned on. The random code generator 120 is included in the semiconductor memory device and generates a random code ASC in response to the power-up signal PVCCH. The address scrambler 130 transforms bits of a first address ADD in response to the random code ASC to generate a second address TA. The first address ADD may be an address that is input to the semiconductor memory device including the address transforming circuit 100 from the outside (e.g., from an external device/system), and the second address TA may be an address that is applied to a row decoder and/or a column decoder.

FIG. 2 is a block diagram of an address transforming circuit 200 in accordance with various embodiments of the inventive concept.

Referring to FIG. 2, the address transforming circuit 200 may include a power-up signal generator 110, a random code generator 120, an address scrambler 130, a code control circuit 140, and a ZQ code generator 150.

The power-up signal generator 110 generates a power-up signal PVCCH when power to be supplied to the semiconductor memory device is turned on. The random code generator 120 generates a randomized output signal RCO in response to the power-up signal PVCCH. The ZQ code generator 150 generates a ZQ code ZQC based on an output impedance of the semiconductor memory device. The code control circuit 140 generates a random code ASC based on the ZQ code ZQC from the ZQ code generator 150 and the output signal RCO from the random code generator 120. The address scrambler 130 transforms bits of a first address ADD in response to the random code ASC to generate a second address TA. The first address ADD may be an address that is input to the semiconductor memory device including the address transforming circuit 200 from the outside (e.g., from an external device/system), and the second address TA may be an address that is applied to a row decoder and/or a column decoder.

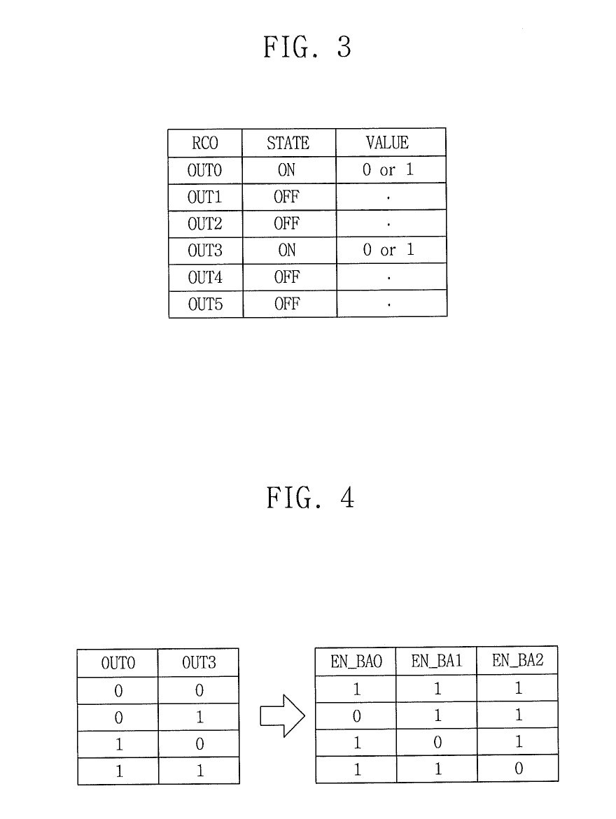

FIGS. 3 and 4 are tables for explaining an address transforming method using random codes in the address transforming circuit shown in FIG. 2. In FIGS. 3 and 4, a method of transforming a bank address of the semiconductor memory device is shown.

As an example, FIG. 3 illustrates that the random code generator 120 in the address transforming circuit 200 in FIG. 2 may generate a randomized output signal RCO including six bits OUT0, OUT1, OUT2, OUT3, OUT4, and OUT5. FIG. 3 further illustrates that only two bits OUT0, OUT3 of the output signal RCO are on-states. The remaining bits (among the six bits OUT0, OUT1, OUT2, OUT3, OUT4, and OUT5 of the output signal RCO from the random code generator 120) are off-states. That is, the example of FIG. 3 illustrates a method of transforming a bank address of the semiconductor memory device in which only two bits OUT0 and OUT3 are used among the six bits OUT0, OUT1, OUT2, OUT3, OUT4, OUT5 output from the random code generator 120. The two bits OUT0 and OUT3 each may have a value of ‘0’ or ‘1’.

Referring to FIG. 4, when both bits OUT0 and OUT3 have values of ‘0’, all first to third bits EN_BA0, EN_BA1, and EN_BA2 of a bank enable signal (e.g., a memory bank enable signal) have a value of ‘1’. When the bits OUT0 and OUT3 of the output signal have values of ‘0’ and ‘1’, respectively, the first bit EN_BA0 of the bank enable signal has a value of ‘0’, and the second and third bits EN_BA1 and EN_BA2 each have a value of ‘1’. When the bits OUT0 and OUT3 of the output signal have values of ‘1’ and ‘0’, respectively, the first bit EN_BA0 of the bank enable signal has a value of ‘1’, the second bit EN_BA1 has a value of ‘0’, and the third bit EN_BA2 has a value of ‘1’. When both bits OUT0 and OUT3 have a value of ‘1’, the first and second bits EN_BA0 and EN_BA1 of the bank enable signal each have a value of ‘1’, and the third bit EN_BA2 has a value of ‘0’.

That is, when both bits OUT0 and OUT3 have a value of ‘0’, phases of all bits EN_BA0, EN_BA1, and EN_BA2 of the bank enable signal do not change. When the bits OUT0 and OUT3 have values of ‘0’ and ‘1’, respectively, a phase of the first bit EN_BA0 of the bank enable signal is reversed (e.g., using the code control circuit 140 and/or the address scrambler 130), but phases of the second and third bits EN_BA1 and EN BA2 do not change. When the bits OUT0 and OUT3 have values of ‘1’ and ‘0’, respectively, phases of the first and third bits EN_BA0 and EN_BA2 of the bank enable signal do not change, and a phase of the second bit EN_BA1 is reversed. When both bits OUT0 and OUT3 have a value of ‘1’, phases of the first and second bits EN_BA0 and EN_BA1 of the bank enable signal do not change, and a phase of the third bit EN_BA2 is reversed.

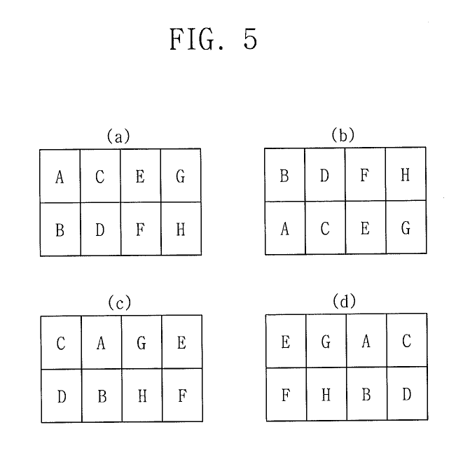

FIG. 5 is a view illustrating an example of a memory cell array designated through a bank address set by the address transforming method shown in FIGS. 3 and 4. FIG. 5(a) represents arrangements of banks of a memory cell array when the bits EN_BA0, EN_BA1 and EN_BA2 of the bank enable signal have values ‘1’, ‘1’ and ‘1’, respectively. FIG. 5(b) represents arrangements of banks of a memory cell array when the bits EN_BA0, EN_BA1 and EN_BA2 of the bank enable signal have values of ‘0’, ‘1’, and ‘1’, respectively. FIG. 5(c) represents arrangements of banks of a memory cell array when the bits EN_BA0, EN_BA1, and EN_BA2 of the bank enable signal have values of ‘1’, ‘0’ and ‘1’, respectively. FIG. 5(d) represents arrangements of banks of a memory cell array when the bits EN_BA0, EN_BA1, and EN_BA2 of the bank enable signal have values of ‘1’, ‘1’ and ‘0’, respectively.

According to the address transforming method shown in FIGS. 3 to 5, a bank address input from the outside (e.g., from an external device/system) accesses other/different banks of the memory cell array whenever a semiconductor memory device is powered on. Thus, in the semiconductor memory device including the address transforming circuit in accordance with various embodiments of the inventive concept, it may be possible to substantially uniformly access all areas of the memory cell array and improve reliability.

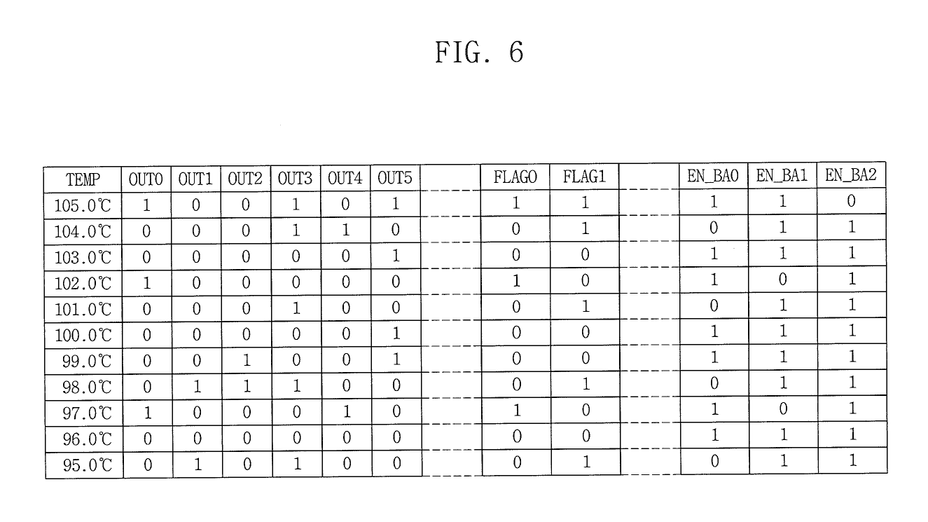

FIG. 6 is a table for explaining an address transforming method using random codes generated based on temperature changes caused by a memory chip.

FIG. 6 illustrates six bits OUT0, OUT1, OUT2, OUT3, OUT4, and OUT5 as the randomized output signal RCO of the random code generator 120 in a range from 95° C. to 105° C. The code control circuit 140 selects specific codes among the six bits OUT0, OUT1, OUT2, OUT3, OUT4, and OUT5 to assign the selected specific codes to FLAG0 and FLAG1 using codes that occur in the interior of the semiconductor memory device, for example, a ZQ code ZQC or a lock code of a delay-locked-loop (DLL). In the example of FIG. 6, a case is shown in which two bits OUT0 and OUT3 among the six bits OUT0, OUT1, OUT2, OUT3, OUT4, and OUT5 are selected and assigned to FLAG0 and FLAG1. The bits EN_BA0, EN_BA1 and EN_BA2 of the bank enable signal may have values as shown in FIG. 6.

The address transforming circuit 200 maps a code assigned to the existing address for a new address to then enable the new address, depending on values of the FLAG0 and FLAG1.

Thus, random codes generated by temperature changes and a ZQ code ZQC or a lock code of the delay-locked-loop (DLL) are scrambled, and the mapping of the bank address is reconstructed. Accordingly, since an input address is mapped to the new address, the address transforming circuit 200 may prevent/impede a specific area, for example, a specific bank of the memory cell array, from being accessed intensively (e.g., from being accessed too frequently), and thus avoid/reduce poor reliability.

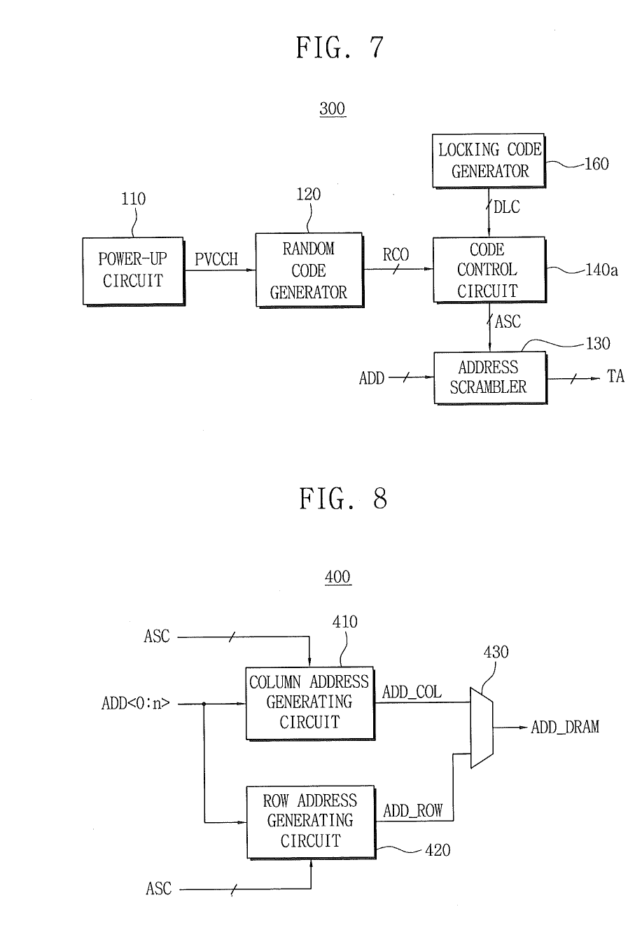

FIG. 7 is a block diagram illustrating an address transforming circuit 300 in accordance with various embodiments of the inventive concept.

Referring to FIG. 7, the address transforming circuit 300 may include a power-up signal generator 110, a random code generator 120, an address scrambler 130, a code control circuit 140a, and a lock code generator 160.

The power-up signal generator 110 generates a power-up signal PVCCH when power to be supplied to the semiconductor memory device is turned on. The random code generator 120 generates a randomized output signal RCO in response to the power-up signal PVCCH. The lock code generator 160 generates a lock code DLC based on a lock state of a clock signal. The clock signal may be performed to operate the lock operation of a delay locked loop circuit included in the semiconductor memory device. The code control circuit 140a generates a random code ASC based on the lock code from the lock code generator 160 and the randomized output signal RCO from the random code generator 120. The address scrambler 130 transforms bits of a first address ADD in response to the random code ASC to generate a second address TA. The first address ADD may be an address that is input to the semiconductor memory device including the address transforming circuit 300 from the outside (e.g., from an external device/system), and the second address TA may be an address that is applied to a row decoder and a column decoder.

FIG. 8 is a block diagram illustrating an address transforming circuit 400 in accordance with various embodiments of the inventive concept.

Referring to FIG. 8, the address transforming circuit 400 may include a column address generating circuit 410, a row address generating circuit 420, and a selection circuit 430.

The column address generating circuit 410 transforms a first address ADD<0:n> in response to the random code ASC to generate a column address ADD_COL. The row address generating circuit 420 transforms a first address ADD<0:n> in response to the random code ASC to generate a row address ADD_ROW. The selection circuit 430 selects one of the column address ADD_COL and the row address ADD_ROW to output the selected address as an address ADD_DRAM of a Dynamic Random Access Memory (DRAM). It will be understood by those skilled in the art, however, that the selected address may alternatively be an address of a different type of memory and is thus not limited to DRAM. Moreover, according to various embodiments, the selection circuit 430 may be a multiplexer.

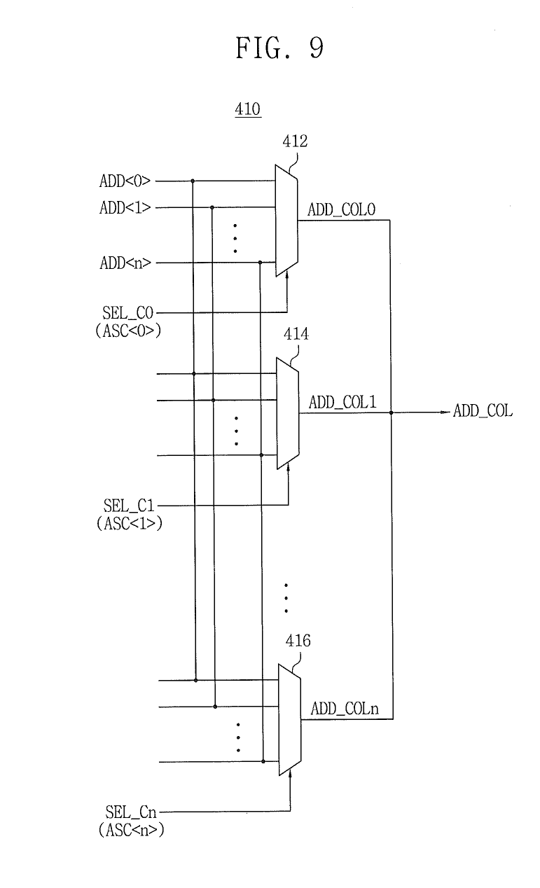

FIG. 9 is a circuit diagram illustrating an example of a column address generating circuit 410 included in the address transforming circuit 400 shown in FIG. 8.

Referring to FIG. 9, the column address generating circuit 410 may include a plurality of multiplexers 412, 414, and 416.

The first multiplexer 412 selects a first address ADD<0:n> in response to a first bit SEL_C0 of a column selection signal to generate a first bit ADD_COL0 of the column address. The second multiplexer 414 selects a first address ADD<0:n> in response to a second bit SEL_C1 of a column selection signal to generate a second bit ADD_COL1 of the column address. The nth multiplexer 416 selects a first address ADD<0:n> in response to an nth bit SEL_Cn of a column selection signal to generate an nth bit ADD_COLn of the column address. The respective bits SEL_C0, SEL_C1, . . . , SEL_Cn of the column selection signal correspond to respective bits ASC<0>, ASC<1>, . . . , ASC<n>of the random code ASC. The random code ASC may be generated by the methods shown in, for example, FIG. 1, 2, or 7.

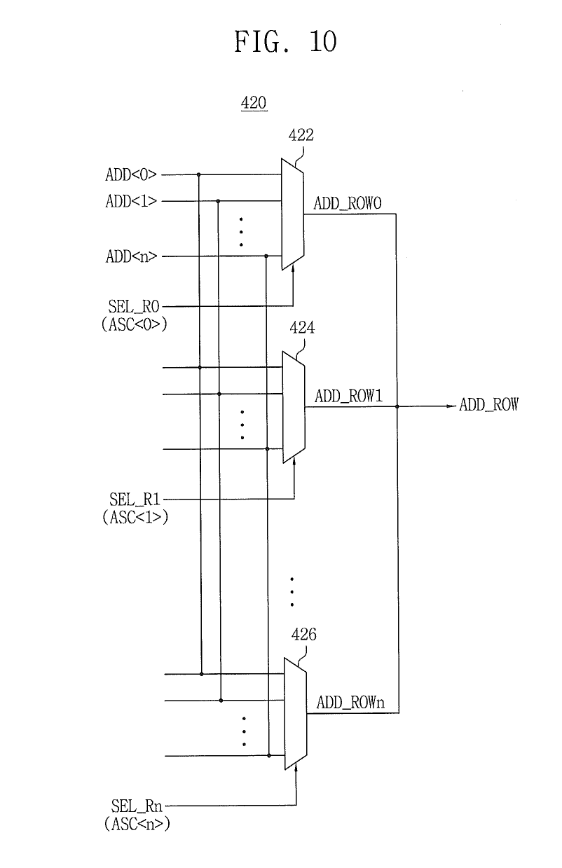

FIG. 10 is a circuit diagram illustrating an example of the row address generating circuit 420 included in the address transforming circuit 400 shown in FIG. 8.

Referring to FIG. 10, the row address generating circuit 420 may include a plurality of multiplexers 422, 424, and 426.

The first multiplexer 422 selects a first address ADD<0:n> in response to a first bit SEL_R0 of a row selection signal to generate a first bit ADD_ROW0 of the row address. The second multiplexer 424 selects a first address ADD<0:n> in response to a second bit SEL_R1 of a row selection signal to generate a second bit ADD _ROW1 of the row address. The nth multiplexer 426 selects a first address ADD<0:n> in response to an nth bit SEL_Rn of a row selection signal to generate an nth bit ADD_ROWn of the row address. The bits SEL_R0, SEL_R1, . . . , SEL_Rn of the row selection signal correspond to bits ASC<0>, ASC<1>, . . . , ASC<n> of the random code ASC, respectively. The random code ASC may be generated by the methods shown in, for example, FIG. 1, 2, or 7.

As shown in FIGS. 8 to 10, in the address transforming circuit in accordance with various embodiments of the inventive concept, it may be possible to randomly access memory cells in memory banks using a random code generated within the semiconductor memory device.

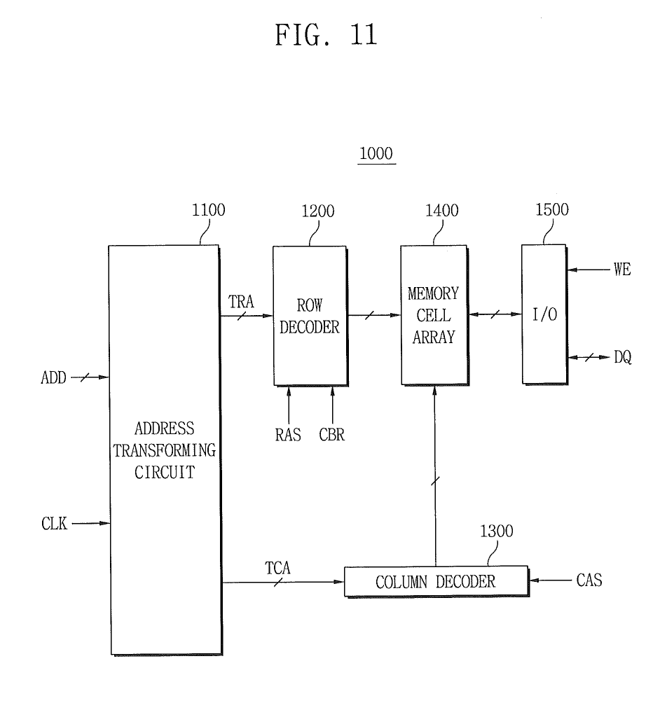

FIG. 11 is a block diagram illustrating an example of a semiconductor memory device 1000 including an address transforming circuit in accordance with various embodiments of the inventive concept.

Referring to FIG. 11, the semiconductor memory device 1000 may include an address transforming circuit 1100, a row decoder 1200, a column decoder 1300, a memory cell array 1400, and an input/output circuit 1500.

The address transforming circuit 1100 transforms bits of a first address ADD in response to a random code generated within a memory chip/semiconductor memory device (e.g., within the address transforming circuit 1100 of the semiconductor memory device 1000) to generate a transformed row address TRA and a transformed column address TCA. The address transforming circuit 1100 can transform bits of the first address ADD in response to a clock signal CLK to generate a transformed row address TRA and a transformed column address TCA. The row decoder 1200 decodes the transformed row address TRA and designates a specific row of the memory cell array 1400 based on the decoded row address. The row decoder 1200 may be controlled by a row address strobe signal RAS and a CAS-before-RAS signal CBR. The column decoder 1300 decodes the transformed column address TCA and designates a specific column of the memory cell array 1400 based on the decoded column address. The column decoder 1300 may be controlled by a column address strobe signal CAS. The input/output circuit 1500 inputs data DQ to the designated memory cell by the row decoder 1200 and the column decoder 1300 in response to a write enable signal WE, or outputs the data DQ from the memory cell designated by the row decoder 1200 and the column decoder 1300.

The address transforming circuit 1100 included in the semiconductor memory device 1000 in FIG. 11 may include one of the address transforming circuits 100, 200, and 300 illustrated in FIGS. 1, 2, and 7, respectively, in accordance with various embodiments of the inventive concept. Accordingly, the semiconductor memory device 1000 may generate a power-up signal when power that is supplied to the memory chip is turned on, and generate a random code in response to the power-up signal. In various embodiments, the random code may be generated based on a temperature of the memory chip. According to various embodiments, the random code may be generated based on the temperature of the memory chip and a ZQ code that is generated based on an output impedance of the memory chip. Moreover, in various embodiments, the random code may be generated based on the temperature of the memory chip and a lock state of a clock signal.

According to various embodiments, the semiconductor memory device 1000 of FIG. 11 may be a dynamic random access memory (DRAM) that is a volatile memory device.

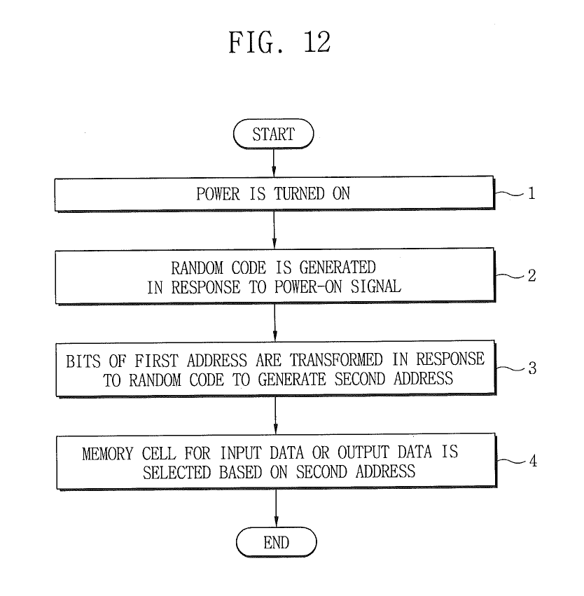

FIG. 12 is a flowchart illustrating an address transforming method of a semiconductor memory device in accordance with various embodiments of the inventive concept.

Referring to FIG. 12, the address transforming method of a semiconductor memory device in accordance with various embodiments of the inventive concept may include the following actions/operations:

(1) Power is turned on (Block 1).

(2) A random code is generated in response to a power-on signal (Block 2).

(3) Bits of a first address are transformed in response to the random code to generate a second address (Block 3).

(4) A memory cell for input data or output data is selected based on the second address (Block 4).

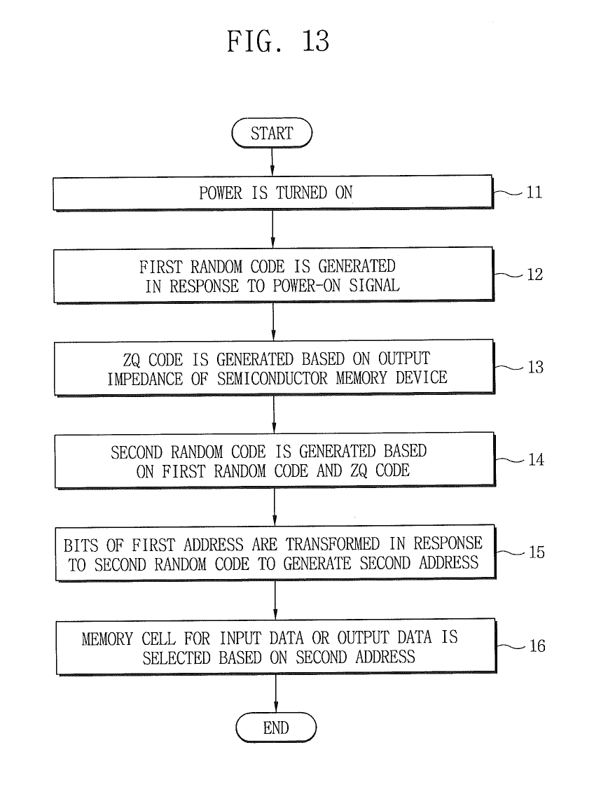

FIG. 13 is a flowchart illustrating an address transforming method of a semiconductor memory device in accordance with various embodiments of the inventive concept.

Referring to FIG. 13, the address transforming method of a semiconductor memory device in accordance with various embodiments of the inventive concept may include the following actions/operations:

(1) Power is turned on (Block 11).

(2) A first random code is generated in response to a power-on signal (Block 12).

(3) A ZQ code is generated based on an output impedance of the semiconductor memory device (Block 13).

(4) A second random code is generated based on the first random code and the ZQ code (Block 14).

(5) Bits of a first address are transformed in response to the second random code to generate a second address (Block 15).

(6) A memory cell for input data or output data is selected based on the second address (Block 16).

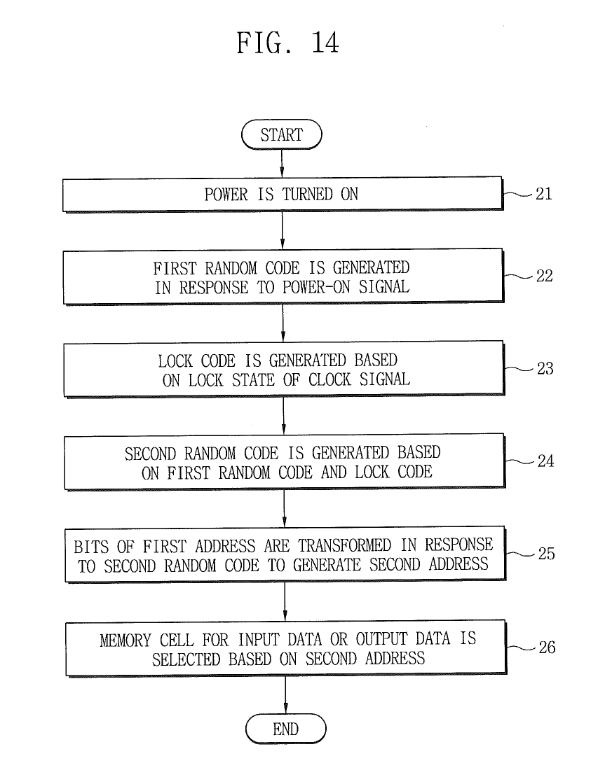

FIG. 14 is a flowchart illustrating an address transforming method of a semiconductor memory device in accordance with various embodiments of the inventive concept.

Referring to FIG. 14, the address transforming method of a semiconductor memory device in accordance with various embodiments of the inventive concept may include the following actions/operations:

(1) Power is turned on (Block 21).

(2) A first random code is generated in response to a power-on signal (Block 22).

(3) A lock code is generated based on a lock state of a clock signal (Block 23).

(4) A second random code is generated based on the first random code and the lock code (Block 24).

(5) Bits of a first address are transformed in response to the second random code to generate a second address (Block 25).

(6) A memory cell for input data or output data is selected based on the second address (Block 26).

As described herein, in the address transforming circuit in accordance with various embodiments of the inventive concept, the bits of the first address are transformed to generate the second address, in response to the random code generated based on the output signal of the random code generator and the ZQ code corresponding to the output impedance of the memory chip. Accordingly, because an address input from the outside (e.g., from a device/system that is external to the semiconductor memory device) is mapped to the new address, the address transforming circuit may prevent/impede a specific area, for example, a specific bank of the memory cell array from being accessed intensively (e.g., from being accessed too frequently), and thus avoid/reduce poor reliability.

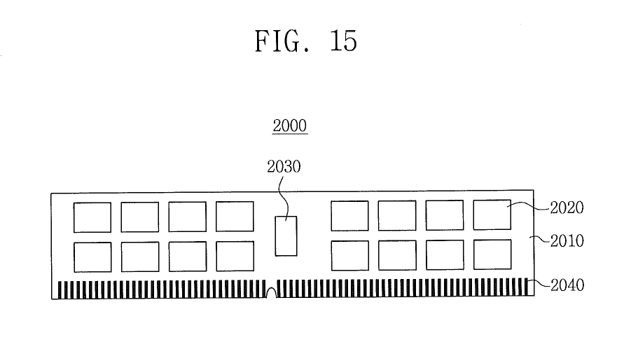

FIG. 15 is a plan view illustrating a semiconductor module 2000 mounted with a semiconductor memory device including an address transforming circuit in accordance with various embodiments of the inventive concept.

Referring to FIG. 15, in various embodiments of the inventive concept, the semiconductor module 2000 may include a module substrate 2010, a plurality of semiconductor memory devices 2020, and a control chip package 2030. The module substrate 2010 may be formed with input/output terminals 2040. The semiconductor memory devices 2020 may include an address transforming circuit in accordance with various embodiments of the inventive concept as described herein.

The semiconductor memory devices 2020 and the control chip package 2030 may be mounted on the module substrate 2010. The semiconductor memory devices 2020 and the control chip package 2030 may be electrically connected to the input/output terminals 2040 in series and/or parallel connection.

In various embodiments, the semiconductor module 2000 may not include the control chip package 2030. The semiconductor memory devices 2020 may include a volatile memory chip such as a dynamic random access memory (DRAM) or a static random access memory (SRAM), a non-volatile memory chip such as a flash memory, a phase change memory, a magnetic random access memory (MRAM), or a resistive random access memory (RRAM), or a combination thereof.

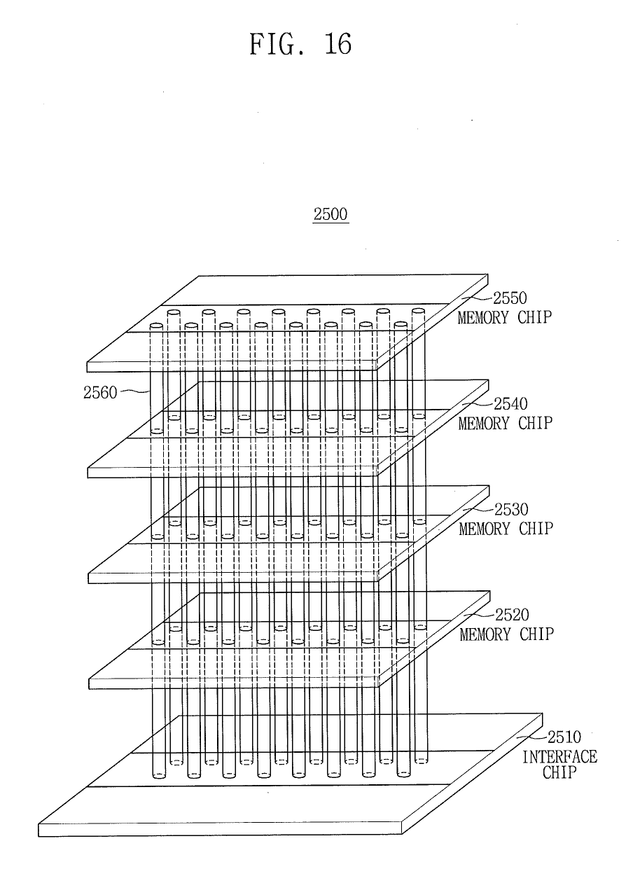

FIG. 16 is a perspective view schematically illustrating a stacked semiconductor device 2500 including an address transforming circuit in accordance with various embodiments of the inventive concept.

Referring to FIG. 16, the stacked semiconductor device 2500 may include an interface chip 2510, and memory chips 2520, 2530, 2540, and 2550, which are electrically connected through through-silicon vias 2560. The stacked semiconductor device 2500 may include any number of the through-silicon vias 2560.

The memory chips 2520, 2530, 2540, and 2550 included in the stacked semiconductor device 2500 may include the address transforming circuit in accordance with various embodiments described herein. Accordingly, the memory chips 2520, 2530, 2540, and 2550 may generate a power-up signal when power to each is turned on, and may generate a random code in response to the power-up signal. The random code may be generated based on a temperature of the respective memory chip. In addition, the random code may be generated based on the temperature of the respective memory chip and a ZQ code generated based on an output impedance of the respective memory chip. Further, the random code may be generated based on the temperature of the respective memory chip and a lock state of a clock signal. Moreover, the interface chip 2510 provides an interface (e.g., performs interfacing operations) between the memory chips 2520, 2530, 2540, and 2550 and external devices.

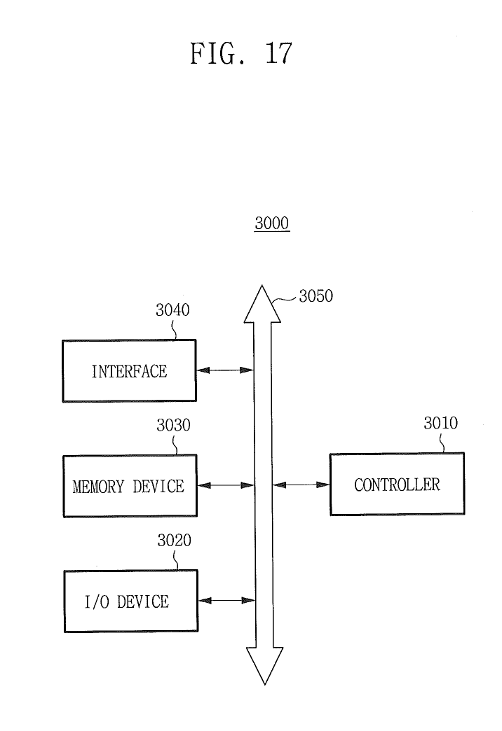

FIG. 17 is a block diagram illustrating an example of an electronic system 3000 in which a semiconductor memory device having an address transforming circuit is included in accordance with various embodiments of the inventive concept.

Referring to FIG. 17, the electronic system 3000 in accordance with various embodiments may include a controller 3010, an input/output (I/O) device 3020, a memory device 3030, an interface 3040, and a bus 3050. The memory device 3030 may be a semiconductor memory device including the address transforming circuit in accordance with various embodiments of the inventive concept. The bus 3050 may function to provide a path for mutually moving data among the controller 3010, the input/output device 3020, the memory device 3030, and the interface 3040.

The controller 3010 may include any one of various logic devices that can perform functions/operations of at least one of a microprocessor, a digital signal processor, and a microcontroller, or similar functions/operations. The input/output device 3020 may include at least one of a key pad, a key board, and a display device. The memory device 3030 may function to store data and/or instructions performed by the controller 3010.

The memory device 3030 may include a volatile memory chip such as a dynamic random access memory (DRAM) or a static random access memory (SRAM), a non-volatile memory chip such as a flash memory, a phase change memory, a magnetic random access memory (MRAM), or a resistive random access memory (RRAM), or a combination thereof The memory device 3030 may be a semiconductor memory device including an address transforming circuit in accordance with various embodiments of the inventive concept.

The interface 3040 may function to transmit/receive data to/from a communication network. The interface 3040 can include an antenna and wired or wireless transceivers or the like to transmit and receive data by wires or wirelessly. In addition, the interface 3040 can include optical fibers to transmit and receive data through the optical fibers. The electronic system 3000 may be further provided with an application chipset, a camera image processor, and an input/output device.

The electronic system 3000 may be implemented as a mobile system, a personal computer, an industrial computer, or a logic system that can perform various functions. For example, the mobile system may be any one of a personal digital assistant (PDA), a portable computer, a web tablet, a mobile phone, a wireless phone, a laptop computer, a memory card, a digital music system, and an information transmitting/receiving system. If the electronic system 3000 is an apparatus that can perform wireless communications, then the electronic system 3000 may be used in a communication system such as Code Division Multiple Access (CDMA), Global System for Mobile communication (GSM), North American Digital Cellular (NADC), Enhanced-Time Division Multiple Access (E-TDMA), Wideband Code Division Multiple Access (WCDMA), or CDMA 2000, among others.

In accordance with various embodiments of the inventive concept, the address transforming circuit may transform the bits of the first address to generate the second address, in response to the random code generated based on the output signal of the random code generator and on the ZQ code corresponding to the output impedance of the memory chip. Accordingly, because an address input from the outside (e.g., from a device/system external to the semiconductor memory device that includes the address transforming circuit) is mapped to the new address, the address transforming circuit may prevent/impede a specific area (e.g., a specific bank of the memory cell array) from being accessed intensively (e.g., too frequently), and thus avoid/reduce poor reliability. Therefore, in the semiconductor memory device having the address transforming circuit, it may be possible to extend the lifespan of the memory device and increase reliability.

The above-disclosed subject matter is to be considered illustrative, and not restrictive, and the appended claims are intended to cover all such modifications, enhancements, and other embodiments, which fall within the true spirit and scope. Thus, to the maximum extent allowed by law, the scope is to be determined by the broadest permissible interpretation of the following claims and their equivalents, and shall not be restricted or limited by the foregoing detailed description.

What is claimed is:

1. An address transforming circuit, comprising:
a random code generator included in a semiconductor memory device and configured to generate a randomized output signal in response to a power-up signal generated when power supplied to the semiconductor memory device is turned on; and
an address scrambler configured to transform bits of a first address in response to the randomized output signal to generate a second address.

2. The circuit according to claim 1, further comprising a power-up signal generator configured to generate the power-up signal.

3. The circuit according to claim 1, further comprising:
a ZQ code generator configured to generate a ZQ code based on an output impedance of the semiconductor memory device; and
a code control circuit configured to generate a random code based on the ZQ code and the randomized output signal of the random code generator.

4. The circuit according to claim 3, wherein the code control circuit and/or the address scrambler is configured to selectively reverse phases of bits of a memory bank enable signal of the semiconductor memory device in response to the randomized output signal of the random code generator.

5. The circuit according to claim 3, wherein:
the randomized output signal of the random code generator comprises a first random code; and
the random code comprises a second random code that is generated based on the ZQ code and the first random code.

6. The circuit according to claim 5, wherein the second random code is generated based on a temperature of the semiconductor memory device and the ZQ code.

7. The circuit according to claim 1, further comprising:
a lock code generator configured to generate a lock code based on a lock state of a clock signal; and
a code control circuit configured to generate a random code based on the lock code and the randomized output signal of the random code generator.

8. The circuit according to claim 7, wherein a lock operation of the clock signal is performed by a delay locked loop circuit.

9. The circuit according to claim 7, wherein the random code is generated based on the lock code and a temperature of the semiconductor memory device.

10. The circuit according to claim 1, wherein the randomized output signal of the random code generator is generated based on a temperature of the semiconductor memory device.

11. A semiconductor memory device comprising:
a memory cell array;
an address transforming circuit configured to transform bits of a first address in response to a random code generated in the semiconductor memory device, and further configured to generate a transformed row address and a transformed column address;
a row decoder configured to decode the transformed row address, and further configured to designate a specific row of the memory cell array based on the decoded row address; and
a column decoder configured to decode the transformed column address, and further configured to designate a specific column of the memory cell array based on the decoded column address, wherein the semiconductor memory device is configured to generate a power-up signal when power supplied to the semiconductor memory device is turned on, and is further configured to generate the random code in response to the power-up signal.

12. The device according to claim 11, wherein:
the address transforming circuit comprises a column address generating circuit configured to generate the transformed column address and a row address generating circuit configured to generate the transformed row address;
the column address generating circuit is configured to generate individual bits of the transformed column address in response to respective individual bits of a column selection signal that corresponds to respective individual bits of the random code; and
the row address generating circuit is configured to generate individual bits of the transformed row address in response to respective individual bits of a row selection signal that corresponds to the respective individual bits of the random code.

13. The device according to claim 11, wherein the random code is generated based on a temperature of the semiconductor memory device and a ZQ code generated based on an output impedance of the semiconductor memory device.

14. The device according to claim 11, wherein the random code is generated based on a temperature of the semiconductor memory device and a lock state of a clock signal.

15. An address transforming method, comprising:
generating a power-up signal when a semiconductor memory device is powered-up;
generating a randomized output signal in response to the power-up signal;
transforming bits of a first address in response to the randomized output signal to generate a second address; and
selecting a memory cell for data input or output using the second address.

16. The method of claim 15, wherein the randomized output signal comprises a first random code, the method further comprising:
generating a ZQ code in response to an output impedance of the semiconductor memory device; and
generating a second random code based on the first random code and the ZQ code, wherein transforming the bits of the first address in response to the randomized output signal comprises transforming the bits of the first address in response to the second random code.

17. The method of claim 15, wherein the randomized output signal comprises a first random code, the method further comprising:
generating a lock code in response to a lock state of a clock signal; and
generating a second random code based on the first random code and the lock code, wherein transforming the bits of the first address in response to the randomized output signal comprises transforming the bits of the first address in response to the second random code.

18. The method of claim 15, wherein generating the randomized output signal comprises generating the randomized output signal based on a temperature of the semiconductor memory device.

19. The method of claim 18, wherein generating the randomized output signal comprises changing values of the randomized output signal in response to a change in the temperature of the semiconductor memory device.

20. The method of claim 19, wherein transforming the bits of the first address in response to the randomized output signal comprises transforming bits of a memory bank enable signal in response to the randomized output signal.
